(19) United States
(12) Patent Application Publication
(10) Pub. No.: US 2026/0068183 A1
(43) Pub. Date: Mar. 5, 2026

(54) HIGH-CAPACITY AND HIGH-BANDWIDTH THREE-DIMENSIONAL DYNAMIC RANDOM-ACCESS MEMORY (3D DRAM) INTEGRATION IN STANDARD DRAM SYSTEM-IN-PACKAGE (SIP)

(71) Applicant: QUALCOMM Incorporated, San Diego, CA (US)

(72) Inventors: Mustafa BADAROGLU, San Diego, CA (US); Jihong CHOI, San Diego, CA (US); Woo Tag KANG, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/313,055

(22) Filed: Aug. 28, 2025

Related U.S. Application Data
(60) Provisional application No. 63/689,366, filed on Aug. 30, 2024.

(51) Int. Cl. H10B 80/00; H01L 25/00; H01L 25/065; H01L 25/18

(52) U.S. Cl. CPC H10B 80/00

(57) ABSTRACT

A three-dimensional (3D) stacked memory package is described. The 3D stacked memory package includes a first plurality of stacked memory dies. The 3D stacked memory package also includes a first base die stacked on the first plurality of stacked memory dies. The 3D stacked memory package further includes a package substrate supporting the first plurality of stacked memory dies. The 3D stacked memory package also includes a first plurality of through silicon vias (TSVs) extending between the first plurality of stacked memory dies and a first compute block on the first base die. The 3D stacked memory package further includes a first set of wire-bonds coupled between the package substrate and a first physical IO interface (PHY) on the first base die.

### CROSS-REFERENCE TO RELATED APPLICATION

The present Application for Patent claims the benefit of U.S. Provisional Patent Application No. 63/689,366 entitled “HIGH-CAPACITY AND HIGH-BANDWIDTH THREE-DIMENSIONAL DYNAMIC RANDOM-ACCESS MEMORY (3D DRAM) INTEGRATION IN STANDARD DRAM SYSTEM-IN-PACKAGE (SIP),” filed Aug. 30, 2024, assigned to the assignee hereof, and expressly incorporated herein by reference in its entirety.

### BACKGROUND OF THE DISCLOSURE

### 1. Field of the Disclosure

Aspects of the present disclosure relate to integrated circuits (ICs) and, more particularly, to a high-capacity and high-bandwidth three-dimensional dynamic random-access memory (3D DRAM) integration in a standard DRAM system-in-package (SiP).

### 2. Description of the Related Art

Memory is a vital component for wireless communications devices. For example, a mobile phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of a processor workload. A semiconductor memory device solution for providing a high-capacity, low-latency, and high-bandwidth memory is an existing goal for system designers.

Semiconductor memory devices include, for example, a static random-access memory (SRAM) and a dynamic random-access memory (DRAM). In practice, memory intensive applications (e.g., artificial intelligence (AI)) consume extensive amounts of DRAM data. State of the art high-bandwidth memory (HBM) DRAM provides advantages in performance for memory-demanding workloads such as generative-AI (e.g., large language models (LLMs)). Edge computing involves high-bandwidth DRAM integration solutions for AI workloads at a reduced form factor for mobile phone integration.

Unfortunately, low-power double data rate (LPDDR) memory used for mobile, and computing has limited bandwidth scaling. Additionally, thermal limitations of HBM significantly restrict further scaling of bandwidth and capacity in HBM DRAM. Therefore, a high-capacity and high-bandwidth 3D DRAM integration in a standard DRAM system-in-package (SiP), is desired.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

A three-dimensional (3D) stacked memory package is described. The 3D stacked memory package includes a first plurality of stacked memory dies. The 3D stacked memory package also includes a first base die stacked on the first plurality of stacked memory dies. The 3D stacked memory package further includes a package substrate supporting the first plurality of stacked memory dies. The 3D stacked memory package also includes a first plurality of through silicon vias (TSVs) extending between the first plurality of stacked memory dies and a first compute block on the first base die. The 3D stacked memory package further includes a first set of wire-bonds coupled between the package substrate and a first physical IO interface (PHY) on the first base die.

A method of forming a three-dimensional (3D) stacked memory package is described. The method includes stacking a first base die on a first plurality of stacked memory dies supported by a package substrate. The method also includes forming a first plurality of through silicon vias (TSVs) extending between the first plurality of memory dies and a first compute block of the first base die. The method further includes forming a first set of wire-bonds between the package substrate and a first physical IO interface (PHY) on the first base die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-chip (SoC), including a high-capacity and high-bandwidth three-dimensional dynamic random-access memory (3D DRAM) integration in a standard DRAM system-in-package (SiP), in accordance with certain aspects of the present disclosure.

FIG. 2 illustrates a cross-sectional view of a stacked integrated circuit (IC) package of the host system-on-chip (SoC) of FIG. 1.

FIG. 3 illustrates a cross-sectional view illustrating the stacked integrated circuit (IC) package of FIG. 2, incorporated into a wireless device, according to one aspect of the present disclosure.

FIG. 4A is a block diagram illustrating a high-capacity and high-bandwidth three-dimensional dynamic random-access memory (3D DRAM) package, according to various aspects of the present disclosure.

FIGS. 4B and 4C illustrate an example of enabling first set of wire-bonds to be formed on a periphery of a top surface of all edges of a first base die, according to various aspects of the present disclosure.

FIGS. 4D and 4E illustrate an example of enabling first set of wire-bonds to be formed on a top surface of a first base die not covered by a second base die, according to various aspects of the present disclosure.

FIGS. 5A to 5O illustrate a process of forming a high-capacity and high-bandwidth three-dimensional dynamic random-access memory (3D DRAM) package of FIG. 4A, according to various aspects of the present disclosure.

FIG. 6 is a process flow diagram illustrating a method for forming a high-capacity and high-bandwidth three-dimensional dynamic random-access memory (3D DRAM) package, according to various aspects of the present disclosure.

FIG. 7A-7B illustrate a process flow diagram illustrating an example implementation of the method illustrated in FIG. 6, according to various aspects of the present disclosure.

FIG. 8A-8B illustrate a process flow diagram illustrating another example implementation of the method illustrated in FIG. 6, according to various aspects of the present disclosure.

FIG. 9 illustrates various apparatuses (e.g., electronic devices) in which any of the semiconductor devices and/or electronic packages disclosed herein may be integrated, according to aspects of the disclosure.

FIG. 10 is a block diagram illustrating a design workstation used for circuit, layout, and logic design of a semiconductor component such as the disclosed high-capacity and high-bandwidth 3D DRAM package.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are three-dimensional (3D) stacked memory package and methods for fabricating the same. In an aspect, The 3D stacked memory package includes a first plurality of stacked memory dies. The 3D stacked memory package also includes a first base die stacked on the first plurality of stacked memory dies. The 3D stacked memory package further includes a package substrate supporting the first plurality of stacked memory dies. The 3D stacked memory package also includes a first plurality of through silicon vias (TSVs) extending between the first plurality of stacked memory dies and a first compute block on the first base die. The 3D stacked memory package further includes a first set of wire-bonds coupled between the package substrate and a first physical IO interface (PHY) on the first base die. In this way, a high-capacity and high-bandwidth 3D DRAM integration in a standard DRAM system-in-package (SiP) can be achieved.

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on”in other configurations.

Memory is a vital component for wireless communications devices. For example, a mobile phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity, high-bandwidth, and low-latency memory solution for scalability of a processor workload. A semiconductor memory device solution for providing a high-capacity, low-latency, and high-bandwidth memory is an existing goal for system designers.

Semiconductor memory devices include, for example, dynamic random-access memory (DRAM). A DRAM memory cell includes one transistor and one capacitor, thereby providing a high degree of integration. DRAM-on-logic, however, is hindered by temperature envelope limitations of DRAM on hotspots on the processor(s) of an SoC. Integrating DRAM on hot compute logic including the processor(s) is problematic because this hot compute logic prevents cooling of the DRAM junction temperatures. These limitations have led to industry implementation of DRAM in a side-by-side configuration with the processor of the hot compute logic.

Semiconductor memory devices include, for example, a static random-access memory (SRAM) and a dynamic random-access memory (DRAM). In practice, memory intensive applications (e.g., artificial intelligence (AI)) consume extensive amounts of DRAM data. State of the art high-bandwidth memory (HBM) DRAM provides advantages in performance and power for memory-demanding workloads such as generative-AI (e.g., large language models (LLMs)). Edge computing involves high-bandwidth DRAM integration solutions for AI workloads at a reduced form factor for mobile phone integration. Unfortunately, low-power double data rate (LPDDR) memory used for mobile, and computing has limited bandwidth scaling. Additionally, thermal limitations of HBM significantly restrict further scaling of bandwidth and capacity in HBM DRAM.

There is a continued demand for high-bandwidth memory (HBM) for large language model (LLM) computation. Unfortunately, it is difficult to increase the bandwidth of HBM memory due to feedthrough connections across the individual HBM dies. Additionally, the LPDDR memory system used for mobile and compute nodes has limited bandwidth scaling. Thermal limitations of HBM inhibit further scaling of bandwidth and capacity in HBM. Therefore, a high-capacity and high-bandwidth three-dimensional (3D) DRAM integration in a standard DRAM system-in-package (SiP), is desired.

Various aspects of the present disclosure provide a high-capacity and high-bandwidth 3D DRAM integration in a standard DRAM system-in-package (SiP). The process flow for fabrication of a high-capacity and high-bandwidth 3D DRAM integration may further include formation of cascaded 3D DRAM stacks supporting a base die. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Various aspects of the present disclosure are directed to a fully cascadable 3D DRAM stack allowing capacity and/or bandwidth scaling. The fully cascadable 3D DRAM stack enables better thermal performance by placing a base die on top for better thermal performance. Additionally, the fully cascadable 3D DRAM stack is compatible with existing DRAM interfaces allowing high-BW memory integration in standard DRAM packages for mobile and compute nodes.

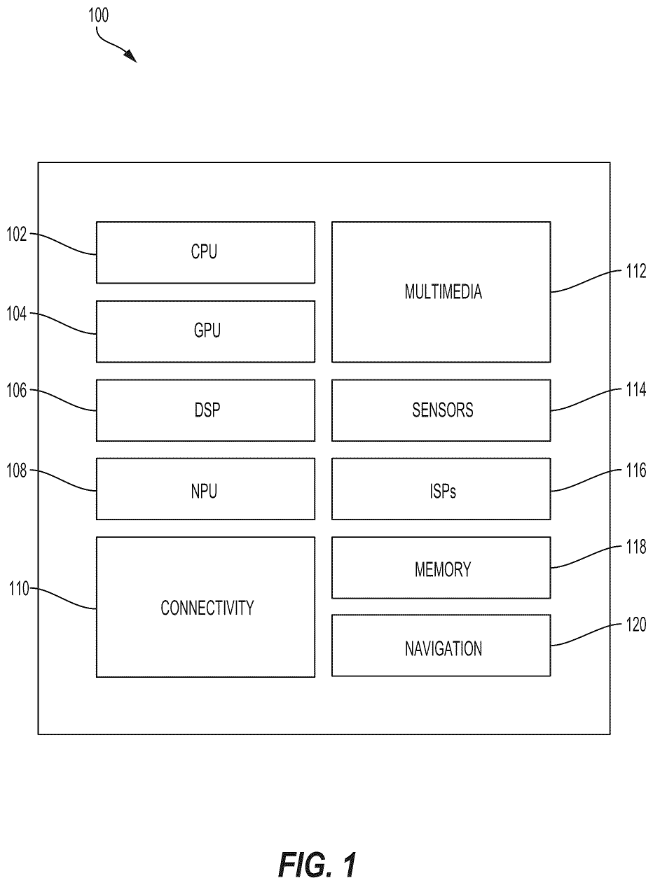

FIG. 1 illustrates an example implementation of a host system-on-chip (SoC) 100, which includes a high-capacity and high-bandwidth three-dimensional dynamic random-access memory (3D DRAM) integration in a standard DRAM system-in-package (SiP), in accordance with certain aspects of the present disclosure. The host SoC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

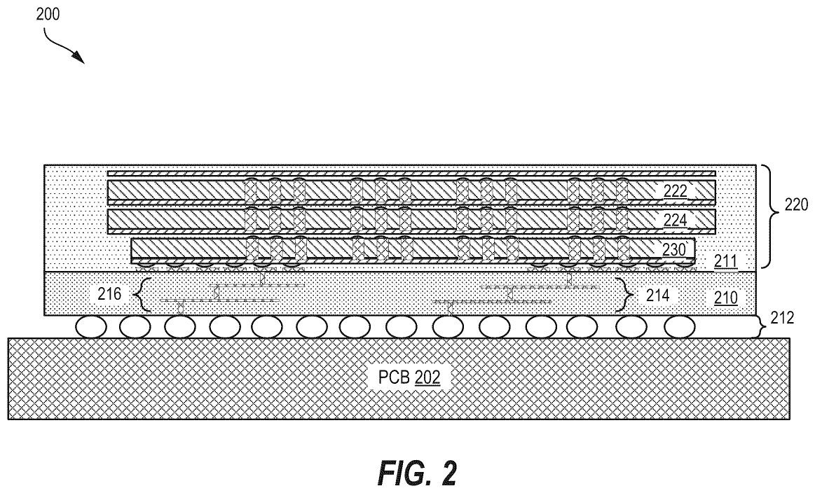

FIG. 2 shows a cross-sectional view of a stacked integrated circuit (IC) package 200 of the host system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SoC 100 of FIG. 1.

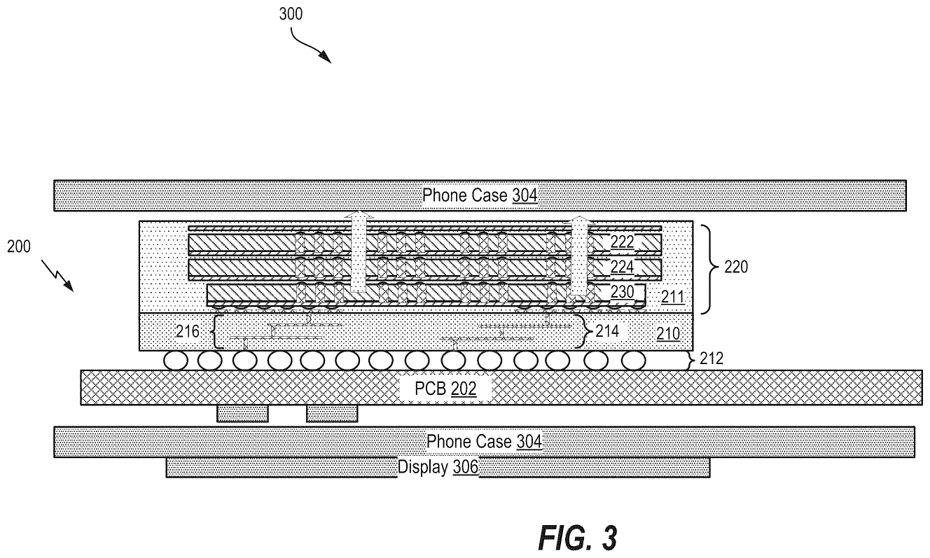

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications. Representatively, the stacked IC package 200 is within a phone case 304, including a display 306.

There is a continued demand for high-bandwidth memory (HBM) for supporting large language model (LLM) computation. Unfortunately, it is difficult to increase the bandwidth of HBM due to feedthrough connections across the individual HBM dies. Additionally, the low-power double data rate (LPDDR) memory system used for mobile and compute nodes has limited bandwidth scaling. Thermal limitations of HBM inhibit further scaling of bandwidth and capacity in HBM. Therefore, a high-capacity and high-bandwidth three-dimensional dynamic random-access memory (3D DRAM) integration in a standard DRAM system-in-package (SiP), is desired.

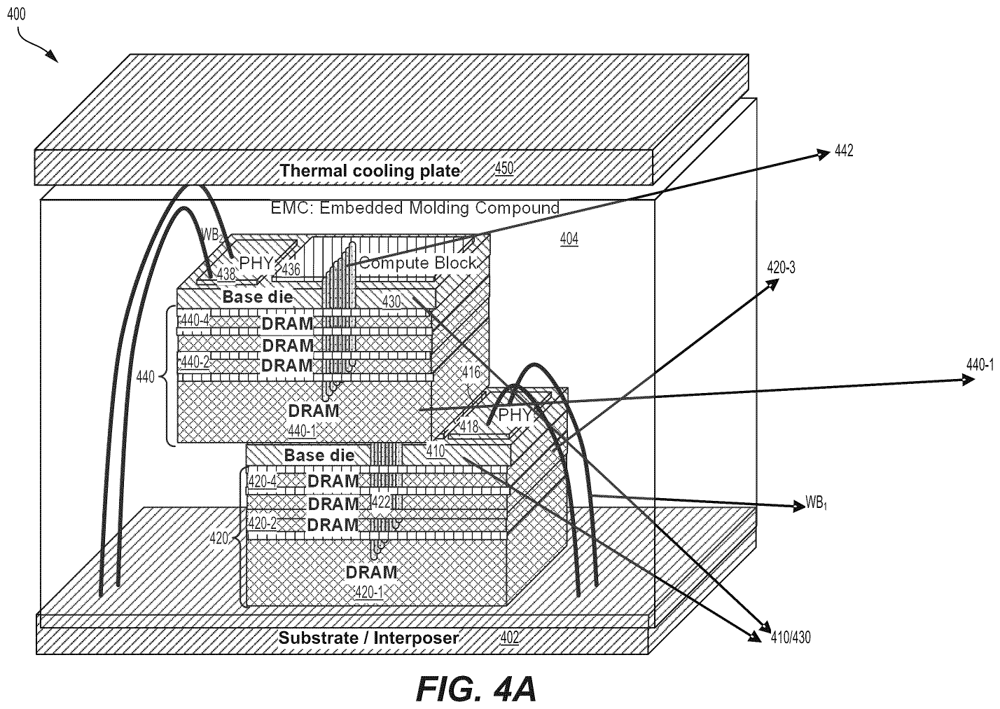

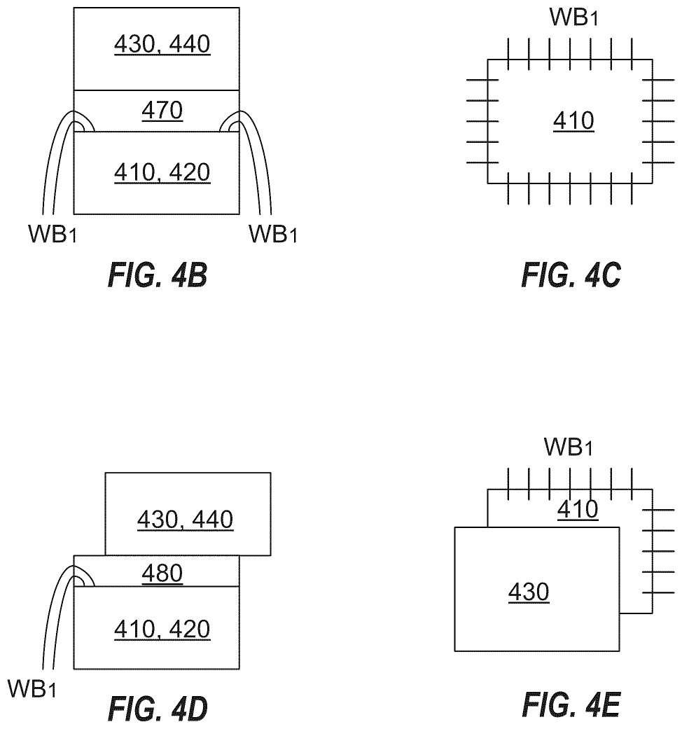

In various aspects of the present disclosure, a fully cascadable 3D DRAM stack allowing capacity and/or bandwidth scaling is described. The fully cascadable 3D DRAM stack enables better thermal performance by placing a base die on top of a stack of DRAM dies for better thermal performance. Additionally, the fully cascadable 3D DRAM stack is compatible with existing DRAM interfaces allowing HBM integration in standard DRAM packages for mobile and compute nodes, for example, as shown in FIG. 4A.

FIG. 4A is a block diagram illustrating a high-capacity and high-bandwidth three-dimensional dynamic random-access memory (3D DRAM) package, according to various aspects of the present disclosure. The high-capacity and high-bandwidth 3D DRAM package may be referred to as a system-in-package (SiP) in some implementations.

As shown in FIG. 4A, a high-capacity and high-bandwidth 3D DRAM package 400 includes a package substrate 402 (or interposer). In this example, the package substrate 402 supports a first memory die stack 420 (420-1, . . . , 420-4), such as a high-bandwidth memory (HBM) DRAM stack of DRAM dies or another like wide input/output (IO) device. In this configuration, the first memory die stack 420 includes high internal bandwidth (e.g., 4 TB/sec) first high-density through silicon vias (TSVs) 422 extending through the first memory die stack 420 for base die computing. For example, a thin memory die 420-3 is configured for the high-density TSVs 422 for enabling the high-capacity and high-bandwidth 3D DRAM package 400. Additionally, the first memory die stack 420 includes a first base memory die 420-1 having a thickness (e.g., 40-50 microns) greater than a thickness (e.g., 10-15 microns) of the thin memory die 420-3 for providing mechanical support as well as a thermal buffer for the first memory die stack 420.

According to various aspects of the present disclosure, a first base die 410 is stacked on the first memory die stack 420 for improving a thermal performance of the high-capacity and high-bandwidth 3D DRAM package 400. The first base die 410 is contacted to the high-density TSVs 422 for access to a first compute block 416 (e.g., a first compute block) of the first base die 410. In this example, the first base die 410 includes a first physical IO interface (PHY) 418 coupled to the package substrate 402 through first wire-bonds (WB₁), such as a first set of wire-bonds. The wire-bonds WB₁ may support a standard external bandwidth (e.g., 40-180 GB/sec). The thickness of the first base memory die 420-1 and the thin memory die 420-3 may be selected based on a desired length (e.g., 50-100 microns) of the first wire-bonds WB₁.

According to various aspects of the present disclosure, a second memory die stack 440 is stacked on the first compute block 416 of the first base die 410. In this configuration, the second memory die stack 440 (440-1, . . . , 440-4) is an HBM core stack of DRAM dies or another like wide IO device. Additionally, the second memory die stack 440 includes second high-density TSVs 442 extending through the second memory die stack 440 for base die computing. For example, the second memory die stack 440 includes a second base memory die 440-1 having a thickness (e.g. 40-50 microns) greater than the thin (e.g., 10-15 microns) memory die (e.g., the second memory die 440-2, the third memory die 440-3 or the fourth memory die 440-4) for providing mechanical support as well as a thermal buffer from the first compute block 416 of the first base die 410 on the first memory die stack 420.

According to various aspects of the present disclosure, a second base die 430 is stacked on the second memory die stack 440 for improving a thermal performance of the high-capacity and high-bandwidth 3D DRAM package 400. The second base die 430 is contacted to the second high-density TSVs 442 for access to a second compute block 436 of the second base die 430. In this example, the second base die 430 includes a second physical IO interface (PHY) 438 coupled to the package substrate 402 through second wire-bonds (WB₂), such as a second set of wire-bonds. The wire-bonds WB₂ may also support a standard external bandwidth (e.g., 40-60 GB/sec).

In an aspect, the second base die 430, and hence the second plurality of stacked memory dies 440, may completely overlap the first base die 410 as seen in FIG. 4B. In this instance, a film-on-wire adhesive 470 may be in between the first base die 410 and the second plurality of stacked memory dies 440. A technical advantage of the of the film-on-wire adhesive 470 is that the first set of wire-bonds WB₁ may be formed on a periphery of a top surface adjacent to all four edges of the first base die 4C as illustrated in FIG. 4C. In FIGS. 4B and 4C, while not shown, it should be noted that the second set of wire-bonds WB₂ are formed on a top surface of the second base die 440.

In another aspect, the second base die 430, and hence the second plurality of stacked memory dies 440, may partially overlap the first base die 410 as seen in FIG. 4D. In this instance, a die attach film 480 may be in between the first base die 410 and the second plurality of stacked memory dies 440. A technical advantage of the of the die attach film 480 is that it can be made relatively thin, and therefore, help with thermal performance. However, it can be difficult to form wire-bonds within the die attach film 480. Thus, the first set of wire-bonds WB₁ may be formed on the top surface of the base die not overlapped by the second plurality of stacked memory dies 440.

Referring back to FIG. 4A, an embedded molding compound (EMC) 404 is deposited on the package substrate 402, the sidewalls of the first memory die stack 420 and the second memory die stack 440, the second base die 430 and a portion of the first base die 410. Once the EMC 404 is deposited, a thermal cooling plate 450 is formed on the EMC 404, which may be composed of epoxy, or other like molding compound.

For further enhanced thermal performance, the base dies 410, 430 is preferred to be close to the thermal cooling plate 450. For example, the first base die 410 may be located closer than the first plurality of stacked memory dies 420. Alternatively or in addition thereto, the second base die 430 may be located closer than the second plurality of stacked memory dies 440.

As shown in FIG. 4A, the high-capacity and high-bandwidth 3D DRAM package 400 is configured as a cascaded stack for increased capacity and bandwidth from the first memory die stack 420 and the second memory die stack 440. The cascaded stack configuration of the high-capacity and high-bandwidth 3D DRAM package 400 supports an increased rank as well as an increased number of channels for providing scaling flexibility in capacity and bandwidth. Additionally, placing the PHY 418/438 (and repair circuits) on the first base die 410 and the second base die 430 reduces the DRAM overhead.

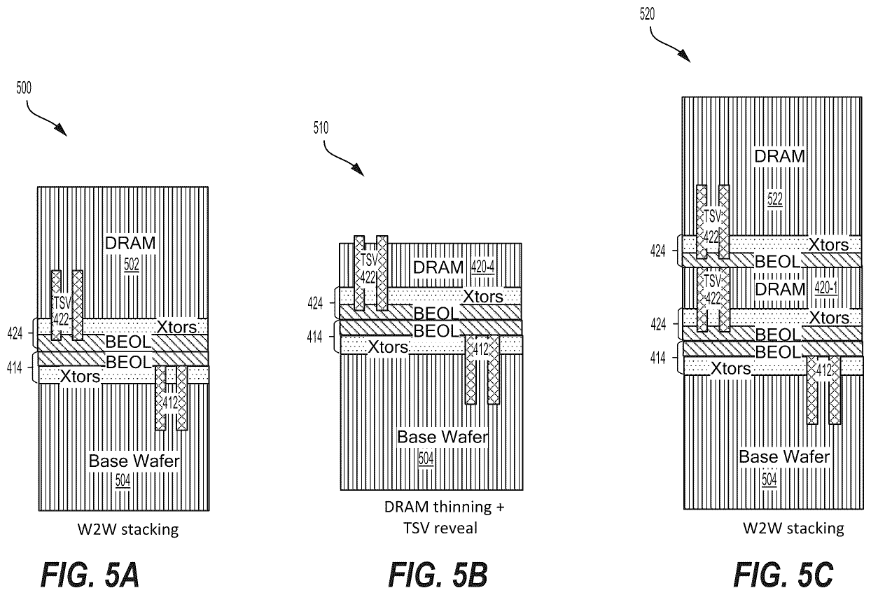

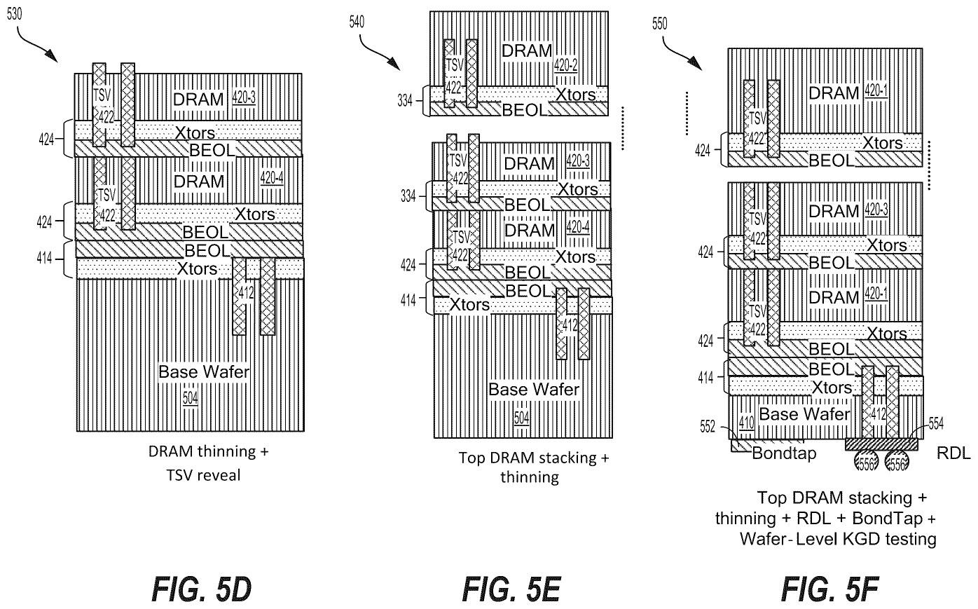

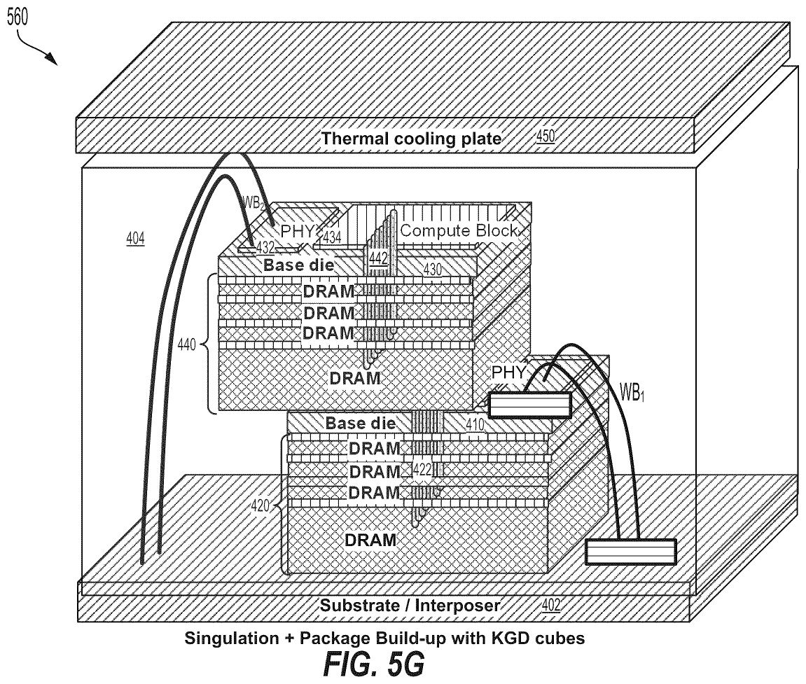

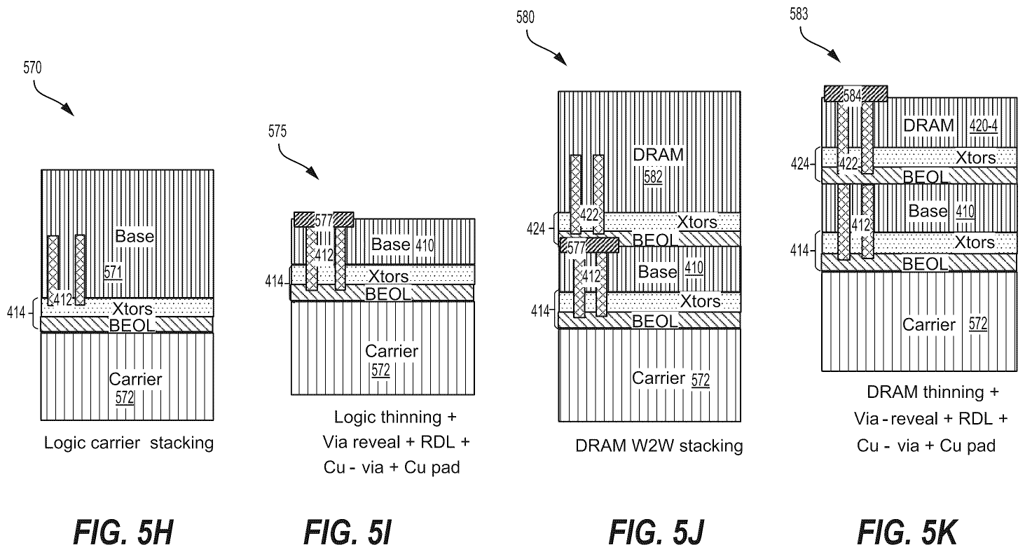

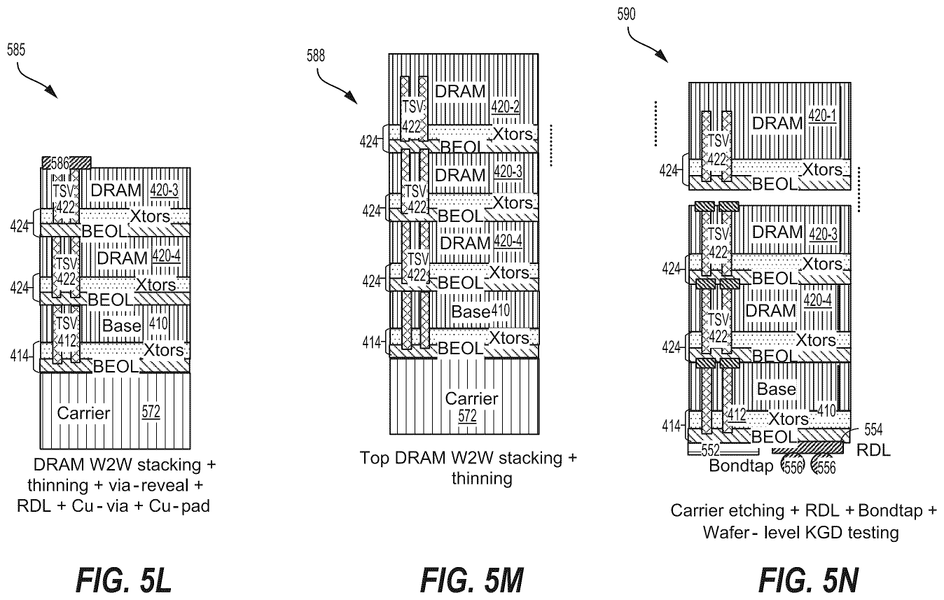

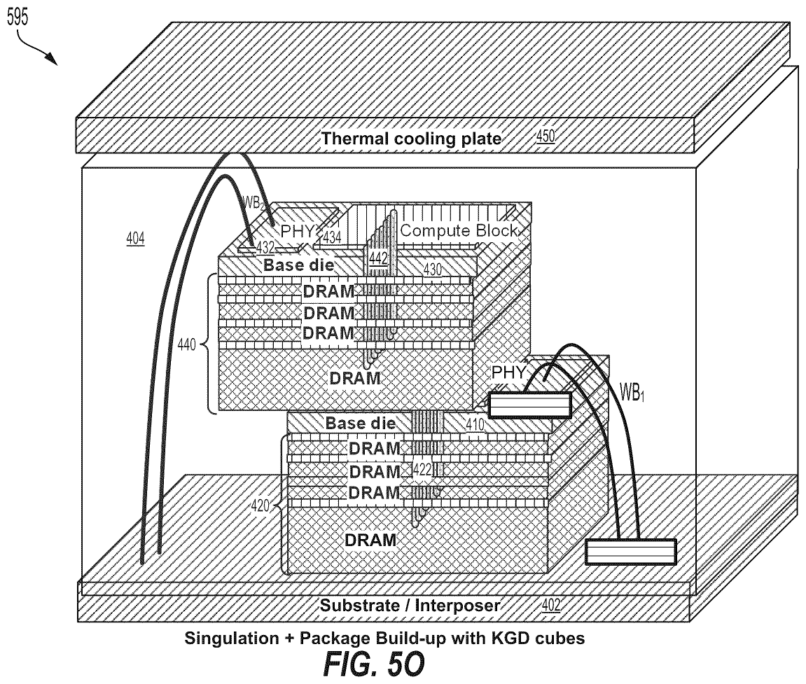

In some implementations, the high-capacity and high-bandwidth 3D DRAM package 400 is configured for full wafer-level known good die (KGD) testing of through bumps before the singulation and packaging process. Additionally, thin (e.g., ˜10 micron thick) DRAM wafers support a wafer-to-wafer stacking flow with specified form factors. A process of forming the high-capacity and high-bandwidth 3D DRAM package 400 is illustrated, for example, in FIGS. 5A to 5G and FIGS. 5H to 5O.

FIGS. 5A to 5G illustrate a process of forming the high-capacity and high-bandwidth three-dimensional dynamic random-access memory (3D DRAM) package 400 of FIG. 4A in a base face-to-face with DRAM configuration, according to various aspects of the present disclosure. The high-capacity and high-bandwidth 3D DRAM package 400 process begins in FIG. 5A.

FIG. 5A illustrates a first step 500 in the process of forming the high-capacity and high-bandwidth 3D DRAM package 400, according to various aspects of the present disclosure. In this instance, process of forming a four DRAM die stack is presented. However, it should be noted that the number of DRAM dies in a stack can be any number. At the first step 500, a DRAM wafer-die 502 is stacked face-down on a first base wafer-die 504 that is face-up according to a wafer-to-wafer (W2W) stacking process. In this example, the base wafer-die 504 includes an active layer 414 having a front-end-of-line (FEOL) layer, including transistors (Xtors), and a back-end-of-line (BEOL) layer on the FEOL layer. Similarly, the DRAM wafer-die 502 includes an active layer 424 having an FEOL layer (e.g., Xtors), and a BEOL layer contacted to the BEOL layer of the base wafer-die 504, according to a face-to-face (F2F) stacking.

In this example, a via-middle and redistribution layer (RDL) process forms logic/signal through silicon vias (TSV) 412 through the base wafer-die 504 and into the BEOL layer of the active layer 414 of the base wafer-die 504. Similarly, a via-middle and RDL process forms the high-density TSVs 422 through the DRAM wafer-die 502 and into the BEOL layer of the active layer 424 of the DRAM wafer-die 502. A flow with via-last (e.g. thinning the wafer from the backside followed by etch from the backside to land on BEOL metal, and forming TSV by liner deposition and metal electroplating) could also be employed without loss of intent in the desired structure in the step 500.

FIG. 5B illustrates a second step 510 in the process of forming the high-capacity and high-bandwidth 3D DRAM package 400, according to various aspects of the present disclosure. At the second step 510, the DRAM wafer-die 502 of FIG. 5A is thinned to form a fourth memory die 420-4, face-down (e.g., having the active layer 424 on the active layer 414 of the base wafer-die 504). In this example, thinning of the DRAM wafer-die 502 of FIG. 5A reveals the high-density TSVs 422 through a backside of the fourth memory die 420-4.

FIG. 5C illustrates a third step 520 in the process of forming the high-capacity and high-bandwidth 3D DRAM package 400, according to various aspects of the present disclosure. At the third step 520, a DRAM wafer-die 522 is stacked with wafer-to-wafer (W2W) stacking on the fourth memory die 420-4. In this example, the DRAM wafer-die 522 includes an active layer 424 having an FEOL layer, including transistors (Xtors), and a BEOL layer on an FEOL layer. Additionally, a via-middle and RDL process forms the high-density TSVs 422 through the DRAM wafer-die 522 and into the BEOL layer of the active layer 424 of the DRAM wafer-die 522. A flow with via-last (e.g. thinning the wafer from the backside followed by etch from the backside to land on BEOL metal, and forming TSV by liner deposition and metal electroplating) could also be employed without loss of intent in the desired structure in the step 520.

FIG. 5D illustrates a fourth step 530 in the process of forming the high-capacity and high-bandwidth 3D DRAM package 400, according to various aspects of the present disclosure. At the fourth step 530, the DRAM wafer-die 522 of FIG. 5C is thinned to form a third memory die 420-3, face-down (e.g., having the active layer 424 on the fourth memory die 420-4). In this example, thinning of the DRAM wafer-die 522 of FIG. 5C reveals the high-density TSVs 422 through a backside of the third memory die 420-3.

FIG. 5E illustrates a fifth step 540 in the process of forming the high-capacity and high-bandwidth 3D DRAM package 400, according to various aspects of the present disclosure. At the fifth step 540, a DRAM wafer-die is stacked with W2W stacking on the third memory die 420-3 and thinned to form a second memory die 420-2, face-down (e.g., having the active layer 424 on the third memory die 420-3). In this example, the via-last/via-middle and RDL process forms the high-density TSVs 422 through the second memory die 420-2, the FEOL layer and into the BEOL layer of the active layer 424 of the second memory die 420-2. As described, the first memory die 420-1 is configured as a base memory die having an increased thickness (e.g., 40-50 microns) for providing mechanical support as well as a thermal buffer. Additionally, the second memory die 420-2, the third memory die 420-3, and the fourth memory die 420-4, may be referred to as thin memory dies (e.g., 10-15 micron thickness), relative to the first memory die 420-1 (e.g., base memory die).

FIG. 5F illustrates a sixth step 550 in the process of forming the high-capacity and high-bandwidth 3D DRAM package 400, according to various aspects of the present disclosure. A DRAM wafer-die is stacked with W2W stacking on the second memory die 420-2 (not shown) and thinned to form a first base memory die 420-1, face-down (e.g., having the active layer 424 on the second memory die 420-2). In this example, the via-last/via-middle and RDL process forms the high-density TSVs 422 in the first base memory die 420-1, the FEOL layer and into the BEOL layer of the active layer 424 of the first base memory die 420-1.

At the sixth step 550, the base wafer-die 504 of FIG. 5E is thinned to form the first base die 410. In this example, thinning of the base wafer-die 504 reveals the logic/signal TSVs 412 through the first base die 410 and into the BEOL layer of the active layer 414 of the first base die 410 at a backside of the first base die 410. Additionally, a bondtap 552 is formed on the backside of the first base die 410 to enable wire-bond connection (e.g., WB₁/WB₂). In various aspects of the present disclosure, etching of the first base die 410 is performed to form a redistribution layer (RDL) 554 on the backside of the first base die 410, and micro-bumps 556 are formed on the RDL 554. According to various aspects of the present disclosure, probing of the micro-bumps 556 enables full wafer-level testing as well as known good die (KGD) testing.

FIG. 5G illustrates a last step 560 in the process of forming the high-capacity and high-bandwidth 3D DRAM package 400, according to various aspects of the present disclosure. At the last step 560, singulation and package build-up of the memory die/base die stack of FIG. 5F is performed. This process also includes wire-bond formation, deposition of the EMC 404 followed by formation of the thermal cooling plate 450 to complete formation of the high-capacity and high-bandwidth 3D DRAM package 400 using KGD DRAM cubes.

FIGS. 5H to 5O illustrate a process of forming the high-capacity and high-bandwidth 3D DRAM package 400 of FIG. 4A in a base face-to-back with DRAM configuration, according to various aspects of the present disclosure. The high-capacity and high-bandwidth 3D DRAM package 400 begins in FIG. 5H.

FIG. 5H illustrates a first step 570 in the process of forming the high-capacity and high-bandwidth 3D DRAM package 400, according to various aspects of the present disclosure. At the first step 500, a base wafer-die 571 is stacked face-down on a carrier wafer 572 according to a logic carrier stacking. In this example, the base wafer-die 571 includes an active layer 414 having a front-end-of-line (FEOL) layer, including transistors (Xtors), and a back-end-of-line (BEOL) layer on the FEOL layer. In this example, a via-middle and redistribution layer (RDL) process forms the logic/signal TSVs 412 through the base wafer-die 571 and into the BEOL layer of the active layer 414 of the base wafer-die 571.

FIG. 5I illustrates a second step 575 in the process of forming the high-capacity and high-bandwidth 3D DRAM package 400, according to various aspects of the present disclosure. At the second step 575, the base wafer-die 571 of FIG. 5H is thinned to form the first base die 410. In this example, thinning of the base wafer-die 571 of FIG. 5H reveals the logic/signal TSVs 412 through a backside of the first base die 410. Additionally, an RDL 577 is formed on the backside of the first base die 410 and contacted to the logic/signal TSVs 412.

FIG. 5J illustrates a third step 580 in the process of forming the high-capacity and high-bandwidth 3D DRAM package 400, according to various aspects of the present disclosure. At the third step 580, a DRAM wafer-die 582 is stacked face-down on the first base die 410 that is face-down according to a wafer-to-wafer (W2W) stacking. In this example, the DRAM wafer-die 582 includes an active layer 424 having an FEOL layer (e.g., Xtors), and a BEOL layer contacted to the RDL 577 on the backside of the first base die 410, according to a face-to-back (F2B) stacking. In this example, a via-middle and RDL process forms the high-density TSVs 422 through the DRAM wafer-die 582 and into the BEOL layer of the active layer 424 of the DRAM wafer-die 582.

FIG. 5K illustrates a fourth step 583 in the process of forming the high-capacity and high-bandwidth 3D DRAM package 400, according to various aspects of the present disclosure. At the fourth step 583, the DRAM wafer-die 582 of FIG. 5J is thinned to form a fourth memory die 420-4, face-down (e.g., having the active layer 424 on the backside of the first base die 410). In this example, thinning of the DRAM wafer-die 582 of FIG. 5J reveals the high-density TSVs 422 through a backside of the fourth memory die 420-4. Additionally, an RDL 584 is formed on the backside of the fourth memory die 420-4 and contacted to the high-density TSVs 422.

FIG. 5L illustrates a fifth step 585 in the process of forming the high-capacity and high-bandwidth 3D DRAM package 400, according to various aspects of the present disclosure. At the fifth step 585, a DRAM wafer-die is stacked with wafer-to-wafer (W2W) stacking on the fourth memory die 420-4. In this example, the DRAM wafer-die is thinned to form a third memory die 420-3, which includes an active layer 424 having an FEOL layer, including transistors (Xtors), and a BEOL layer on an FEOL layer, the BEOL layer contacted to the RDL 584, as shown in FIG. 5K. Additionally, a via-middle and RDL process forms the high-density TSVs 422 through the third memory die 420-3 and into the BEOL layer of the active layer 424 of the DRAM wafer-die 522. An RDL 586 is formed on the backside of the third memory die 420-3.

FIG. 5M illustrates a sixth step 588 in the process of forming the high-capacity and high-bandwidth 3D DRAM package 400, according to various aspects of the present disclosure. At the sixth step 588, a DRAM wafer-die is stacked with W2W stacking on the third memory die 420-3 and thinned to form a second memory die 420-2, face-down (e.g., having the active layer 424 on the third memory die 420-3 and contacted to the RDL 586, as shown in FIG. 5L on the backside of the third memory die 420-3. In this example, the high-density TSVs 422 are formed in the second memory die 420-2 using a via-middle and RDL process.

FIG. 5N illustrates a seventh step 590 in the process of forming the high-capacity and high-bandwidth 3D DRAM package 400, according to various aspects of the present disclosure. At the seventh step 590, a DRAM wafer-die is stacked with W2W stacking on the second memory die 420-2 (not shown) and thinned to form a first base memory die 420-1, face-down (e.g., having the active layer 424 on the second memory die 420-2). In this example, the via-last/via-middle and RDL process forms the high-density TSVs 422 in the first base memory die 420-1, the FEOL layer and into the BEOL layer of the active layer 424 of the first base memory die 420-1.

At the seventh step 590, carrier etching removes the carrier wafer 572 from the first base die 410. In this example, a bondtap 552 is formed on the backside of the first base die 410 to enable wire-bond connection (e.g., WB₁/WB₂). In various aspects of the present disclosure, etching of the base die first forms a redistribution layer (RDL) 554 on the backside of the first base die 410, and micro-bumps 556 are formed on the RDL 554. According to various aspects of the present disclosure, probing of the micro-bumps 556 enables full wafer-level testing as well as known good die (KGD) testing.

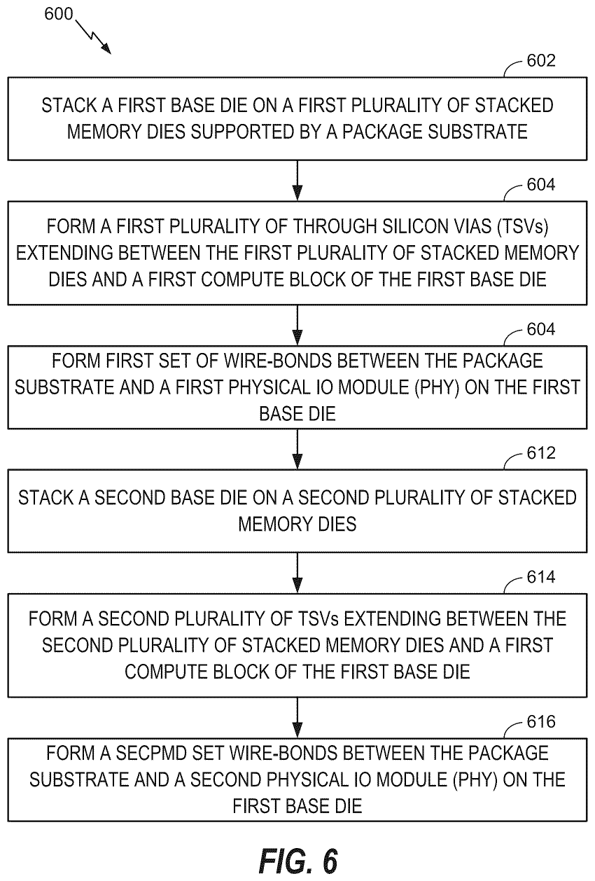

FIG. 5O illustrates a last step 595 in the process of forming the high-capacity and high-bandwidth 3D DRAM package 400, according to various aspects of the present disclosure. At the last step 595, singulation and package build-up of the memory die/base die stack of FIG. 5N is performed. This process also includes wire-bond formation, deposition of the EMC 404 followed by formation of the thermal cooling plate 450 to complete formation of the high-capacity and high-bandwidth 3D DRAM package 400 using KGD DRAM cubes. A process flow for forming the high-capacity and high-bandwidth 3D DRAM package is illustrated, for example, in FIG. 6.

FIG. 6 is a process flow diagram illustrating a method 600 for forming a high-capacity and high-bandwidth three-dimensional dynamic random-access memory (3D DRAM) package, according to various aspects of the present disclosure. The method 600 begins at block 602, in which a first base die is stacked on a first plurality of stacked memory dies supported by a package substrate. For example, as shown in FIG. 4A, the first base die 410 is stacked on the first memory die stack 420 for improving a thermal performance of the high-capacity and high-bandwidth 3D DRAM package 400.

At block 604, through silicon vias (TSVs) are formed to extend between the first plurality of memory dies and a first compute block of the first base die. For example, as shown in FIG. 4A, the first memory die stack 420 includes high internal bandwidth (e.g., 4 TB/sec) first high-density through silicon vias (TSVs) 422 extending through the first memory die stack 420 for base die computing. For example, a thin memory die 420-3 is configured for the high-density TSVs 422 for enabling the high-capacity and high-bandwidth 3D DRAM package 400.

At block 606, wire-bonds are formed between the package substrate and a first physical IO interface (PHY) on the first base die. For example, as shown in FIG. 4A, the first base die 410 includes the first physical IO interface (PHY) 418 coupled to the package substrate 402 through first wire-bonds (WB₁), such as a first set of wire-bonds. The wire-bonds WB₁ may support a standard external bandwidth (e.g., 40-180 GB/sec). The thickness of the first base memory die 420-1 and the thin memory die 420-3 may be selected based on a desired length (e.g., 50-100 microns) of the first wire-bonds WB₁.

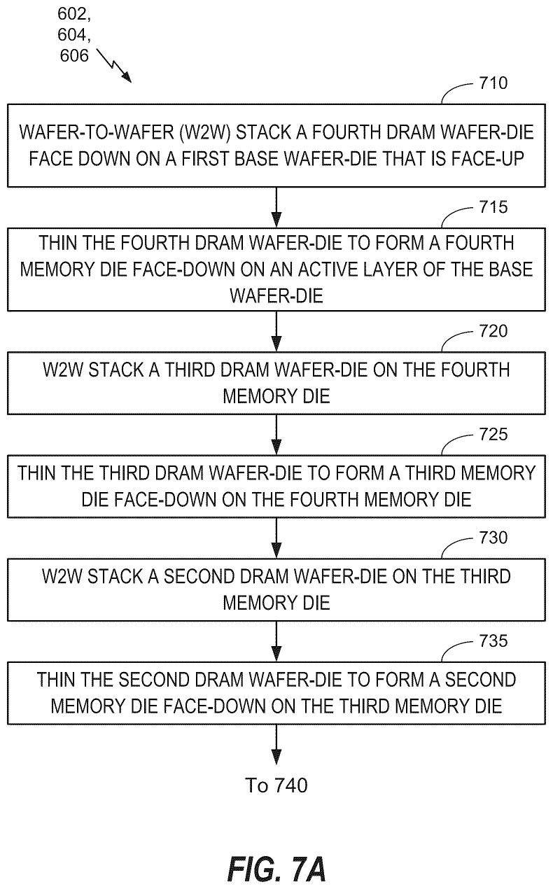

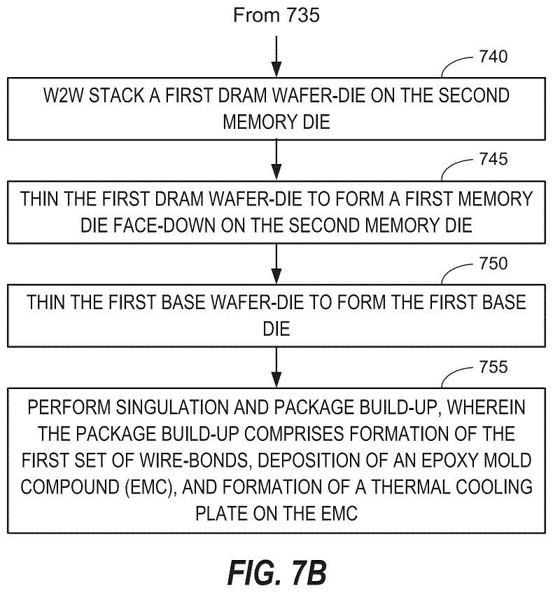

FIGS. 7A and 7B illustrate a process flow for a particular implementation of the blocks of FIG. 6. At block 710, a fourth DRAM wafer-die 502 can be wafer-to-wafer (W2W) stacked on a first base wafer-die 504 that is face-up. Block 710 may correspond to FIG. 5A.

At block 715, the fourth DRAM wafer-die 502 thinned to form a fourth memory die 420-4 face-down on an active layer 414 of the base wafer-die 504. Block 715 may correspond to FIG. 5B.

At block 720, a third DRAM wafer-die 522 may be W2W stacked on the fourth memory die 420-4. Block 725 may correspond to FIG. 5C.

At block 725, the third DRAM wafer-die 522 may be thinned to form a third memory die 420-3 face-down on the fourth memory die 420-4. Block 725 may correspond to FIG. 5D.

At block 730, a second DRAM wafer-die may be W2W stacked on the third memory die 420-3. Block 725 may correspond to FIG. 5E.

At block 735, the second DRAM wafer-die may be thinned to form a second memory die 420-2 face-down on the third memory die 420-3. Block 730 may also correspond to FIG. 5E.

At block 740, a first DRAM wafer-die may be W2W stacked on the second memory die 420-2. Block 740 may correspond to FIG. 5F.

At block 745, the first DRAM wafer-die may be thinned to form a first memory die 420-1 face-down on the second memory die 420-2. Block 740 may also correspond to FIG. 5F.

At block 750, the first base wafer-die 504 may be thinned to form the first base die 410. Block 750 may correspond to FIG. 5G.

At block 755, singulation and package build-up of the memory die/base die stack of FIG. 5F is performed. The process may also include wire-bond formation, deposition of the EMC 404, and formation of the thermal cooling plate 450. Block 755 may also correspond to FIG. 5G.

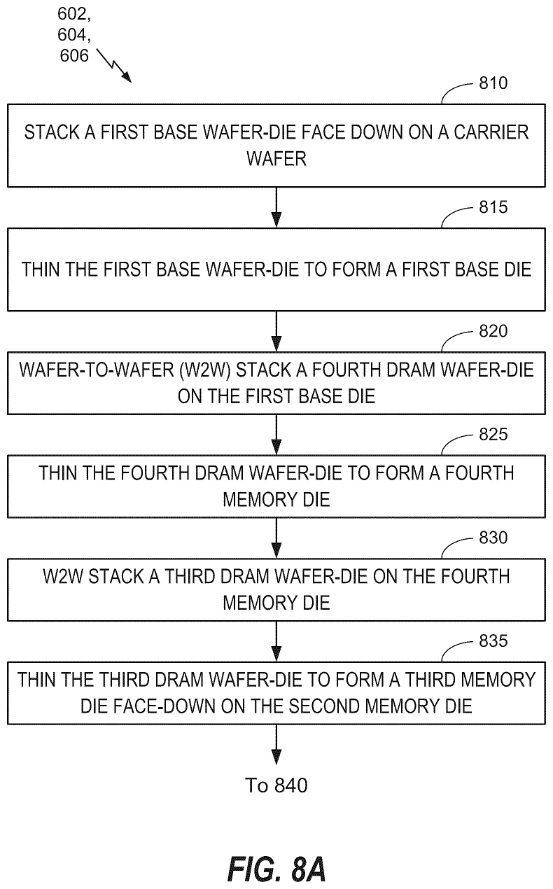

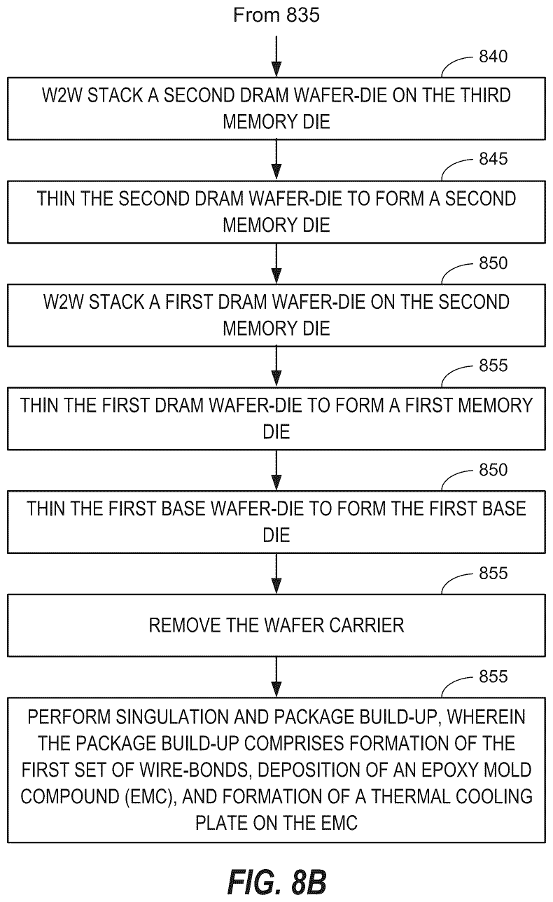

FIGS. 8A and 8B illustrate another process flow for a particular implementation of the blocks of FIG. 6. At block 810, a first base wafer-die 571 may be stacked face-down on a carrier wafer 572 according to a logic carrier stacking. Block 810 may correspond to FIG. 5H.

At block 815, the first base wafer-die 571 may be thinned to form the first base die 410. Block 815 may correspond to FIG. 5I.

At block 820, a fourth DRAM wafer-die 582 may be W2W stacked face-down on the first base die 410 that is face-down. Block 820 may correspond to FIG. 5J.

At block 825, the fourth DRAM wafer-die 582 may be thinned to form a fourth memory die 420-4, face-down. Block 825 may correspond to FIG. 5K.

At block 830, W2W stack a third DRAM wafer-die on the fourth memory die 420-4. Block 830 may correspond to FIG. 5L.

At block 835, the third DRAM wafer-die may be thinned to form the third memory die 420-3, face down. Block 830 may also correspond to FIG. 5L.

At block 840, W2W stack a second DRAM wafer-die on the third memory die 420-3. Block 840 may correspond to FIG. 5M.

At block 845, the second DRAM wafer-die may be thinned to form the second memory die 420-2, face down. Block 845 may also correspond to FIG. 5M.

At block 850, W2W stack a first DRAM wafer-die on the second memory die 420-2. Block 850 may correspond to FIG. 5N.

At block 855, the first DRAM wafer-die may be thinned to form the first memory die 420-1, face down. Block 855 may also correspond to FIG. 5N.

At block 860, the carrier wafer 572 may be removed. Block 860 may correspond to FIG. 5O.

At block 865, singulation and package build-up of the memory die/base die stack of FIG. 5F is performed. The process may also include wire-bond formation, deposition of the EMC 404, and formation of the thermal cooling plate 450. Block 755 may also correspond to FIG. 5O.

The following should be noted regarding the flow indicated in FIG. 6-8. Unless otherwise indicated, the flow of blocks do not necessarily limit the ordering in which the blocks may be performed. In other words, the blocks may be performed in any order that is logical.

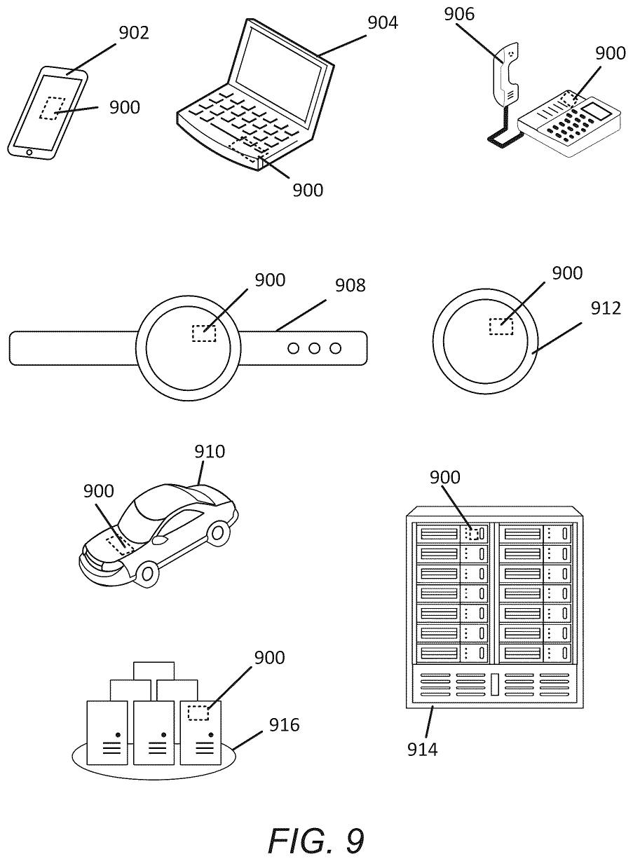

FIG. 9 illustrates various apparatuses (e.g., electronic devices) in which any of the semiconductor devices and/or electronic packages (e.g., 3D stacked memory packages) disclosed herein may be integrated, according to aspects of the disclosure. In an aspect, the semiconductor devices and/or electronic packages 900 may be integrated into user equipment (UE), including, by way of example and not limitation, a mobile phone device 902, a laptop computer device 904, a fixed-location terminal device 906, or a wearable device 908.

In other aspects, the semiconductor devices and/or electronic packages 900 may be integrated into electronic devices utilized in automotive applications. Such devices may include, by way of example and not limitation, sensors, controllers, processors, infotainment devices, and the like, which may be installed in a vehicle 910.

In yet other aspects, the semiconductor devices and/or electronic packages 900 may be integrated into a short-range device (SRD) 912. The SRD 912 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 900 may be integrated into a server 914. The server 914 may comprise a computer system configured to provide services, data, or resources to other computers over a network. Such a server 914 may include one or more processors, integrated memory devices, power supplies, or other components mounted in one or more racks.

In yet other aspects, the semiconductor devices and/or electronic packages 900 may be integrated into a data center 916. The data center 916 may comprise a facility configured with one or more servers, storage devices, networking devices, and other supporting devices for storing, processing, and managing data.

The semiconductor devices and/or electronic packages 900 disclosed herein may be fabricated in various package configurations, including, but not limited to, side-by-side (SxS) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 902, 904, 906, 908, 910, 912, 914, and 916 illustrated in FIG. 9 are merely exemplary. Other apparatuses in which the semiconductor devices and/or electronic packages 900 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

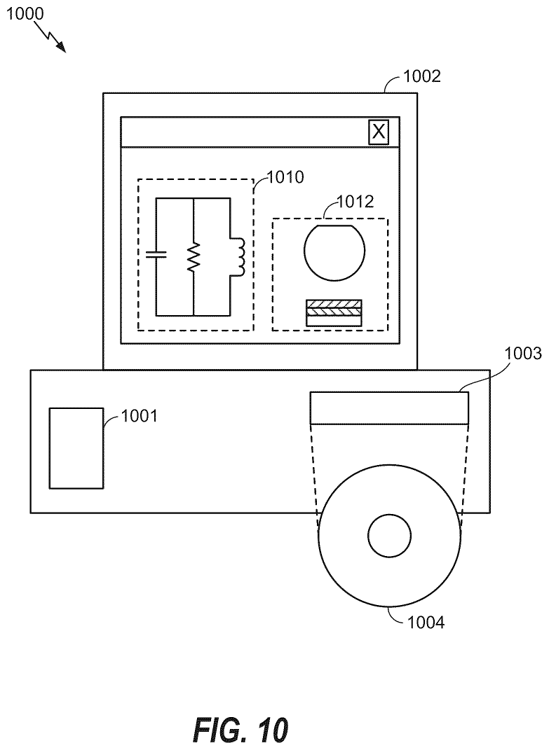

FIG. 10 is a block diagram illustrating a design workstation 1000 used for circuit, layout, and logic design of a semiconductor component, such as the high-capacity and high-bandwidth 3D DRAM package disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the high-capacity and high-bandwidth 3D DRAM package. A storage medium 1004 is provided for tangibly storing the design of the circuit 1010 or the semiconductor component 1012 (e.g., the high-capacity and high-bandwidth 3D DRAM package). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. A three-dimensional (3D) stacked memory package, comprising:
a first plurality of stacked memory dies;
a first base die stacked on the first plurality of stacked memory dies;
a package substrate supporting the first plurality of stacked memory dies;
a first plurality of through silicon vias (TSVs) extending between the first plurality of stacked memory dies and a first compute block on the first base die; and
a first set of wire-bonds coupled between the package substrate and a first physical IO interface (PHY) on the first base die.
2. The 3D stacked memory package of clause 1, further comprising:
a second plurality of stacked memory dies;
a second base die stacked on the second plurality of stacked memory dies;
a second plurality of TSVs extending between the second plurality of stacked memory dies and a second compute block on the second base die; and
a second set of wire-bonds coupled between the package substrate and a second physical IO interface (PHY) on the second base die.
3. The 3D stacked memory package of clause 2, wherein the second plurality of stacked memory dies are stacked on the first compute block on the first base die.
4. The 3D stacked memory package of any of clauses 1-3, wherein the first set of wire-bonds are formed on a periphery of a top surface adjacent to all edges of the first base die.
5. The 3D stacked memory package of clause 4, wherein the second plurality of stacked memory dies completely overlaps the first base die.
6. The 3D stacked memory package of any of clauses 1-3,
wherein the second plurality of stacked memory dies partially overlaps the first base die, and
wherein the first set of wire-bonds are formed on a top surface of the base die not overlapped by the second plurality of stacked memory dies.
7. The 3D stacked memory package of any of clauses 1-6,
wherein the first plurality of stacked memory dies comprises a first 3D dynamic random-access memory (DRAM) stack, or
wherein the second plurality of stacked memory dies comprises a second 3D DRAM stack, or
both.
8. The 3D stacked memory package of any of clauses 1-7,
wherein the first plurality of stacked memory dies comprises a first base memory die having a thickness greater than a thickness of one of the other of the first plurality of stacked memory dies on the first base memory die, or
wherein the second plurality of stacked memory dies comprises a second base memory die having a thickness greater than a thickness of one of the other of the second plurality of stacked memory dies on the first base memory die, or
both.
9. The 3D stacked memory package of any of clauses 1-8, further comprising:
an embedded molding compound (EMC) on the first base die, sidewalls of the first plurality of stacked memory dies, and the package substrate; and
a thermal cooling plate on the EMC.
10. The 3D stacked memory package of clause 9,
wherein the first base die is closer to the thermal cooling plate than the first plurality of stacked memory dies, or
wherein the second base die is closer to the thermal cooling plate than the second plurality of stacked memory dies, or
both.
11. The 3D stacked memory package of any of clauses 9-10, wherein the EMC comprises epoxy.
12. The 3D stacked memory package of any of clauses 1-11, wherein the first set of wire-bonds are coupled to a bondtap on the first base die.
13. The 3D stacked memory package of any of clauses 1-12,
wherein the first plurality of stacked memory dies comprises a first high-bandwidth memory (HBM) DRAM stack, or
wherein the second plurality of stacked memory dies comprises a second HBM DRAM stack, or
both.
14. The 3D stacked memory package of any of clauses 1-13, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.
15. A method of forming a three-dimensional (3D) stacked memory package, the method comprising:
stacking a first base die on a first plurality of stacked memory dies supported by a package substrate;
forming a first plurality of through silicon vias (TSVs) extending between the first plurality of stacked memory dies and a first compute block of the first base die; and
forming a first set of wire-bonds between the package substrate and a first physical IO interface (PHY) on the first base die.
16. The method of clause 15, further comprising:
stacking a second base die stacked on a second plurality of stacked memory dies;
forming a second plurality of TSVs extending between the second plurality of stacked memory dies and a second compute block on the second base die; and
forming a second set of wire-bonds coupled between the package substrate and a second physical IO interface (PHY) on the second base die.
17. The method of clause 15, wherein the second plurality of stacked memory dies are stacked on the first compute block on the first base die.
18. The method of any of clauses 15-17, wherein the first set of wire-bonds are formed on a periphery of a top surface adjacent to all edges of the first base die.
19. The method of clause 18, wherein the second plurality of stacked memory dies completely overlaps the first base die.
20. The method of any of clauses 15-17,
wherein the second plurality of stacked memory dies partially overlaps the first base die, and
wherein the first set of wire-bonds are formed on a top surface of the base die not overlapped by the second plurality of stacked memory dies.
21. the method of clauses 15-20,
wherein the first plurality of stacked memory dies comprises a first 3D dynamic random-access memory (DRAM) stack, or
wherein the second plurality of stacked memory dies comprises a second 3D DRAM stack, or
both.
22. The method of clauses 15-21,
wherein the first plurality of stacked memory dies comprises a first base memory die having a thickness greater than a thickness of one of the other of the first plurality of stacked memory dies on the first base memory die, or
wherein the second plurality of stacked memory dies comprises a second base memory die having a thickness greater than a thickness of one of the other of the second plurality of stacked memory dies on the first base memory die, or
both.
23. The method of clauses 15-22, further comprising:
depositing an embedded molding compound (EMC) on the first base die, sidewalls of the first plurality of stacked memory dies, and the package substrate; and
forming a thermal cooling plate on the EMC.
24. The method of clause 23,
wherein the first base die is closer to the thermal cooling plate than the first plurality of stacked memory dies, or
wherein the second base die is closer to the thermal cooling plate than the second plurality of stacked memory dies, or both.
25. The method of clauses 23-24, wherein the EMC comprises an epoxy.
26. The method of clauses 15-25, wherein the first set of wire-bonds are coupled to a bondtap on the first base die.
27. The method of clauses 15-26,
wherein the first plurality of stacked memory dies comprises a first high-bandwidth memory (HBM) DRAM stack, or
wherein the second plurality of stacked memory dies comprises a second HBM DRAM stack, or
both.
28. The method of clauses 15-27, wherein stacking the first base die, forming the first plurality of TSVs, and forming the first set of wire-bonds comprise:
wafer-to-wafer (W2W) stacking a fourth DRAM wafer-die on a first base wafer-die that is face-up;
thinning the fourth DRAM wafer-die to form a fourth memory die face-down on an active layer of the base wafer-die;
W2W stacking a third DRAM wafer-die on the fourth memory die;
thinning the third DRAM wafer-die to form a third memory die face-down on the fourth memory die;
W2W stacking a second DRAM wafer-die on the third memory die;
thinning the second DRAM wafer-die to form a second memory die face-down on the third memory die;
W2W stacking a first DRAM wafer-die on the second memory die;
thinning the first DRAM wafer-die to form a first memory die face-down on the second memory die;
thinning the first base wafer-die to form the first base die; and
performing singulation and package build-up, wherein the package build-up comprises formation of the first set of wire-bonds, deposition of an epoxy mold compound (EMC), and formation of a thermal cooling plate on the EMC.
29. The method of clauses 15-27, wherein stacking the first base die, forming the first plurality of TSVs, and forming the first set of wire-bonds comprise:
stacking a first base wafer-die face-down on a carrier wafer;
thinning the first base wafer-die to form the first base die;
wafer-to-wafer (W2W) stacking a fourth DRAM wafer-die on the first base die that is face-down;
thinning the fourth DRAM wafer-die to form a fourth memory die face-down;
W2W stacking a third DRAM wafer-die on the fourth memory die;
thinning the third DRAM wafer-die to form a third memory die on the fourth memory die;
W2W stacking a second DRAM wafer-die on the third memory die;
thinning the second DRAM wafer-die to form a second memory die on the third memory die;
W2W stacking a first DRAM wafer-die on the second memory die;
thinning the first DRAM wafer-die to form a first memory die on the second memory die;
removing the carrier wafer; and
performing singulation and package build-up, wherein the package build-up comprises formation of the first set of wire-bonds, deposition of an epoxy mold compound (EMC), and formation of a thermal cooling plate on the EMC.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random-access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) stacked memory package, comprising:
a first plurality of stacked memory dies;
a first base die stacked on the first plurality of stacked memory dies;
a package substrate supporting the first plurality of stacked memory dies;
a first plurality of through silicon vias (TSVs) extending between the first plurality of stacked memory dies and a first compute block on the first base die; and
a first set of wire-bonds coupled between the package substrate and a first physical IO interface (PHY) on the first base die.

2. The 3D stacked memory package of claim 1, further comprising:
a second plurality of stacked memory dies;
a second base die stacked on the second plurality of stacked memory dies;
a second plurality of TSVs extending between the second plurality of stacked memory dies and a second compute block on the second base die; and
a second set of wire-bonds coupled between the package substrate and a second physical IO interface (PHY) on the second base die.

3. The 3D stacked memory package of claim 2, wherein the second plurality of stacked memory dies are stacked on the first compute block on the first base die.

4. The 3D stacked memory package of claim 1, wherein the first set of wire-bonds are formed on a periphery of a top surface adjacent to all edges of the first base die.

5. The 3D stacked memory package of claim 4, wherein the second plurality of stacked memory dies completely overlaps the first base die.

6. The 3D stacked memory package of claim 1,
wherein the second plurality of stacked memory dies partially overlaps the first base die, and
wherein the first set of wire-bonds are formed on a top surface of the base die not overlapped by the second plurality of stacked memory dies.

7. The 3D stacked memory package of claim 1,
wherein the first plurality of stacked memory dies comprises a first 3D dynamic random-access memory (DRAM) stack, or
wherein the second plurality of stacked memory dies comprises a second 3D DRAM stack, or
both.

8. The 3D stacked memory package of claim 1,
wherein the first plurality of stacked memory dies comprises a first base memory die having a thickness greater than a thickness of one of the other of the first plurality of stacked memory dies on the first base memory die, or
wherein the second plurality of stacked memory dies comprises a second base memory die having a thickness greater than a thickness of one of the other of the second plurality of stacked memory dies on the first base memory die, or
both.

9. The 3D stacked memory package of claim 1, further comprising:
an embedded molding compound (EMC) on the first base die, sidewalls of the first plurality of stacked memory dies, and the package substrate; and
a thermal cooling plate on the EMC.

10. The 3D stacked memory package of claim 9,
wherein the first base die is closer to the thermal cooling plate than the first plurality of stacked memory dies, or
wherein the second base die is closer to the thermal cooling plate than the second plurality of stacked memory dies, or
both.

11. The 3D stacked memory package of claim 1, wherein the first set of wire-bonds are coupled to a bondtap on the first base die.

12. The 3D stacked memory package of claim 1,
wherein the first plurality of stacked memory dies comprises a first high-bandwidth memory (HBM) DRAM stack, or
wherein the second plurality of stacked memory dies comprises a second HBM DRAM stack, or
both.

13. The 3D stacked memory package of claim 1, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

14. A method of forming a three-dimensional (3D) stacked memory package, the method comprising:
stacking a first base die on a first plurality of stacked memory dies supported by a package substrate;
forming a first plurality of through silicon vias (TSVs) extending between the first plurality of stacked memory dies and a first compute block of the first base die; and
forming a first set of wire-bonds between the package substrate and a first physical IO interface (PHY) on the first base die.

15. The method of claim 14, further comprising:
stacking a second base die stacked on a second plurality of stacked memory dies;
forming a second plurality of TSVs extending between the second plurality of stacked memory dies and a second compute block on the second base die; and
forming a second set of wire-bonds coupled between the package substrate and a second physical IO interface (PHY) on the second base die.

16. The method of claim 14, wherein the first set of wire-bonds are formed on a periphery of a top surface adjacent to all edges of the first base die.

17. The method of claim 14,
wherein the second plurality of stacked memory dies partially overlaps the first base die, and
wherein the first set of wire-bonds are formed on a top surface of the base die not overlapped by the second plurality of stacked memory dies.

18. The method of claim 14, further comprising:
depositing an embedded molding compound (EMC) on the first base die, sidewalls of the first plurality of stacked memory dies, and the package substrate; and
forming a thermal cooling plate on the EMC.

19. The method of claim 14, wherein stacking the first base die, forming the first plurality of TSVs, and forming the first set of wire-bonds comprise:
wafer-to-wafer (W2W) stacking a fourth DRAM wafer-die on a first base wafer-die that is face-up;
thinning the fourth DRAM wafer-die to form a fourth memory die face-down on an active layer of the base wafer-die;
W2W stacking a third DRAM wafer-die on the fourth memory die;
thinning the third DRAM wafer-die to form a third memory die face-down on the fourth memory die;
W2W stacking a second DRAM wafer-die on the third memory die;
thinning the second DRAM wafer-die to form a second memory die face-down on the third memory die;
W2W stacking a first DRAM wafer-die on the second memory die;
thinning the first DRAM wafer-die to form a first memory die face-down on the second memory die;
thinning the first base wafer-die to form the first base die; and
performing singulation and package build-up, wherein the package build-up comprises formation of the first set of wire-bonds, deposition of an epoxy mold compound (EMC), and formation of a thermal cooling plate on the EMC.

20. The method of claim 14, wherein stacking the first base die, forming the first plurality of TSVs, and forming the first set of wire-bonds comprise:
stacking a first base wafer-die face-down on a carrier wafer;
thinning the first base wafer-die to form the first base die;
wafer-to-wafer (W2W) stacking a fourth DRAM wafer-die on the first base die that is face-down;
thinning the fourth DRAM wafer-die to form a fourth memory die face-down;
W2W stacking a third DRAM wafer-die on the fourth memory die;
thinning the third DRAM wafer-die to form a third memory die on the fourth memory die;
W2W stacking a second DRAM wafer-die on the third memory die;
thinning the second DRAM wafer-die to form a second memory die on the third memory die;
W2W stacking a first DRAM wafer-die on the second memory die;
thinning the first DRAM wafer-die to form a first memory die on the second memory die;
removing the carrier wafer; and
performing singulation and package build-up, wherein the package build-up comprises formation of the first set of wire-bonds, deposition of an epoxy mold compound (EMC), and formation of a thermal cooling plate on the EMC.
